(19) United States
(12) Patent Application Publication
(10) Pub. No.: US 2007/0101223 A1
(43) Pub. Date: May 3, 2007

(54) Electronic test apparatus and method for testing at least one circuit unit

(76) Inventors: Christian Chetreanu, Munchen (DE); Stefan Gollmer, Munchen (DE); Amir Leber, Cary, NC (US); Roman Mayr, Munchen (DE)

Correspondence Address: JENKINS, WILSON, TAYLOR & HUNT, P. A., 3100 TOWER BLVD, SUITE 1200, DURHAM, NC, 27707, US

(21) Appl. No.: 11/586,370

(22) Filed: Oct. 25, 2006

(30) Foreign Application Priority Data
Oct. 28, 2005 (DE) 102005051814.1-55

(51) Int. Cl. G01R 31/28

(52) U.S. Cl. 714/731

(57) ABSTRACT

An electronic test apparatus for testing at least one circuit unit comprises a clock signal generator for generating a clock signal, a driver device comprising a plurality of driver subunits each generating a phase-shifted driver signal in response to said clock signal, a processing device for processing the phase-shifted driver signals and for comparing actual data being output by at least one circuit unit with desired data generated in the processing device, a connecting device for connecting the processing device to the at least one circuit unit and for transmitting the phase-shifted driver signals, the desired data, and the actual data between the processing device and the at least one circuit unit, and a combinational logic device for combining the phase-shifted driver signals to form a clock combination signal.

### BACKGROUND OF THE INVENTION

The present invention relates, in general, to test systems for testing circuit units to be tested and relates, in particular, to a test apparatus for testing electronic circuit units using a high clock frequency.

In this case, a clock signal is generated in a clock signal generator and is supplied to a driver device for driving the clock signal which has been generated. Specifically, the present invention also relates to a processing device for processing the clock signal and for comparing actual data, which are output from an electronic circuit unit to be tested, with desired data, which are generated in the processing device, and to a connecting device for connecting the processing device to the at least one circuit unit to be tested and for transmitting the clock signal, the desired data and the actual data between the processing device and the at least one circuit unit to be tested.

One known system for testing circuit units to be tested, in particular electronic memory modules, is sold under the name Advantest T5581 H ATE, as disclosed on the GCE Market homepage at the address http://www.gcemarket.com/. However, the 1998 model of the Advantest T5581 system has considerable disadvantages as regards test speed. The specified maximum signal frequency of the Advantest T5581 system is 250 MHz. In order to be able to test electronic circuits units at higher clock frequencies (desired data frequencies), such conventional test systems are disadvantageously not suitable. Providing a faster test system for new generations of memory modules is associated with a cost outlay and economic disadvantages since such test systems are extremely cost-intensive.

FIG. 7 shows a conventional test apparatus for testing circuit units to be tested DUT. The circuit arrangement shown in FIG. 7 corresponds to the conventional Advantest T5581 test system. In this case, a clock signal generator 301 generates a clock signal 307 which is supplied to the circuit units to be tested DUT 101a-101n without its frequency having been changed. The signal which is output from the circuit units to be tested on the basis of the supplied clock signal and the supplied desired data, that is to say the actual data 103a-103n, is then compared in a comparison circuit 201a of the processing device 201. A connecting device 202 comprises, inter alia, a HiFix device. A driver device 602 is finally used to drive the clock signals generated in a waveform generation device to the circuit units to be tested 101a-101n.

A considerable disadvantage of the conventional test apparatus is then that the frequency of the clock signal 307 is restricted. The circuit units to be tested 101a-101n can thus be tested, in a conventional manner, only at the maximum frequency provided by the clock signal 307.

It shall be pointed out that the remaining components of the Advantest 5581 test system shown in FIG. 7 are not essential to understanding the present invention, with the result that they are not described here.

### BRIEF DESCRIPTION OF THE INVENTION

A central idea of the invention is to increase the clock frequency of conventional test systems by supplying a clock signal to different driver subunits, the different driver subunits each having a phase shifter unit for providing a predetermined phase shift. The individual clock signals which have been phase-shifted in a different manner are then combined to form a clock combination signal in such a manner that the number of positive and negative edges of the clock combination signal is increased in comparison with the original clock signal. The number of positive and/or negative edges determines the signal frequency at which one or more circuit units to be tested can be tested.

The basic concept of the invention thus resides in the fact that the driver device used in the electronic test apparatus has a number k of driver subunits, each of the driver subunits respectively generating a phase-shifted driver signal. k driver signals which have been phase-shifted in a different manner can be generated in this way. Provision is also made of a combinational logic device for combining the phase-shifted driver signals generated by the driver subunits to form the clock combination signal.

The number of driver subunits may be two, thus resulting in the advantage that a phase shift of 180° between two different phase-shifted driver signals can be provided in a simple manner.

An advantage of the inventive method and of the inventive apparatus is thus that conventional test systems can also be used to test a new generation of electronic circuit units to be tested, for example memory modules such as DRAMs, in which higher clock frequencies can be processed. Specifically, the advantage is thus that, when using two driver subunits correspondingly having two associated phase shifter units, a clock signal frequency of a conventional test system, such as the Advantest T5581 system described above, which is 250 MHz, can be doubled, that is to say a maximum signal frequency of up to 500 MHz can be used to test the electronic circuit units.

The inventive test apparatus may also afford the advantage that the individual drivers are terminated exactly with a 50 ohm impedance, as a result of which an electromagnetic wave which is transmitted to its circuit unit and continues to propagate to another driver subunit will be absorbed by the transmitter resistor of the latter. The driver subunits are thus advantageously terminated with the line impedance.

The clock combination signal may be expediently provided at twice the frequency of the individual clock signals by the clock combination signal being generated using differential clocking.

The inventive electronic test apparatus and the associated test method thus make it possible to use conventional test systems to test electronic circuit units which are to be tested and require a higher test frequency than that which can be provided by the test system.

According to one aspect of the invention, an electronic test apparatus for testing at least one circuit unit to be tested using actual data which are output from the circuit unit to be tested comprises:
a) a clock signal generator for generating a clock signal;
b) a driver device for driving the clock signal which is generated by the clock signal generator;
c) a processing device for processing the clock signal and for comparing the actual data, which are output by the at least one circuit unit to be tested, with desired data which are generated in the processing device; and
d) a connecting device for connecting the processing device to the at least one circuit unit to be tested and for transmitting the clock signal, the desired data and the actual data between the processing device and the at least one circuit unit to be tested.

The driver device comprises a number k of driver subunits, each of the driver subunits respectively generating a phase-shifted driver signal. Provision is also made of a combinational logic device for combining the phase-shifted driver signals generated by the driver subunits to form a clock combination signal.

According to another aspect of the invention, a method for testing at least one circuit unit to be tested comprises the steps of:
a) using a clock signal generator to generate a clock signal;
b) using a driver device to drive the clock signal generated by the clock signal generator;
c) using a processing device to process the clock signal;
d) using the processing unit to provide desired data;
e) using a connecting device, which is provided between the processing device and the at least one circuit unit to be tested, to transmit the clock signal and actual data, which are output from the circuit unit to be tested on the basis of the desired data, between the processing device and the at least one circuit unit to be tested; and
f) using the processing device to compare the actual data output from the at least one circuit unit to be tested with the desired data generated in the processing device,
   a phase-shifted driver signal respectively being generated using a number k of driver subunits of the driver device, and the phase-shifted driver signals generated by the driver subunits being combined, using a combinational logic device, to form a clock combination signal and being supplied to the circuit unit to be tested.

The number k of driver subunits may be two. The driver subunits may each comprise a phase shifter unit which provides a predetermined phase shift of the driver signal.

The connecting device for connecting the processing device to the at least one circuit unit to be tested and for transmitting the phase-shifted clock signals and the actual data between the processing device and the at least one circuit unit to be tested may comprise a HiFix unit.

The combinational logic device may be in the form of an OR gate.

The clock combination signal may be provided at twice the frequency of the individual clock signals, differential clocking preferably being carried out in this case. Specifically, the clock signal repetition period may be 4 ns.

### DESCRIPTION OF THE SEVERAL VIEWS OF DRAWINGS

Exemplary embodiments of the invention are illustrated in the drawings and are explained in more detail in the following description.

In the drawings:

FIG. 1 is a schematic block diagram of an inventive electronic test apparatus for testing at least one circuit unit to be tested.

FIG. 2 is an arrangement and a timing diagram for generating pulses using phase-shifted driver signals when doubling the frequency of the clock signal in accordance with one preferred exemplary embodiment of the present invention.

FIG. 3 is an arrangement for calibrating the inventive electronic test apparatus.

FIG. 4 is a calibration signal when calibrating using the arrangement illustrated in FIG. 3.

FIG. 5 is a voltage measurement of superimposition of a clock signal and an inverted clock signal.

FIG. 6 is a voltage profile U as a function of a measurement time t with a sine wave.

FIG. 7, as discussed above, is a conventional test apparatus.

### DETAILED DESCRIPTION OF THE INVENTION

In the figures, identical reference symbols denote identical or functionally identical components or steps.

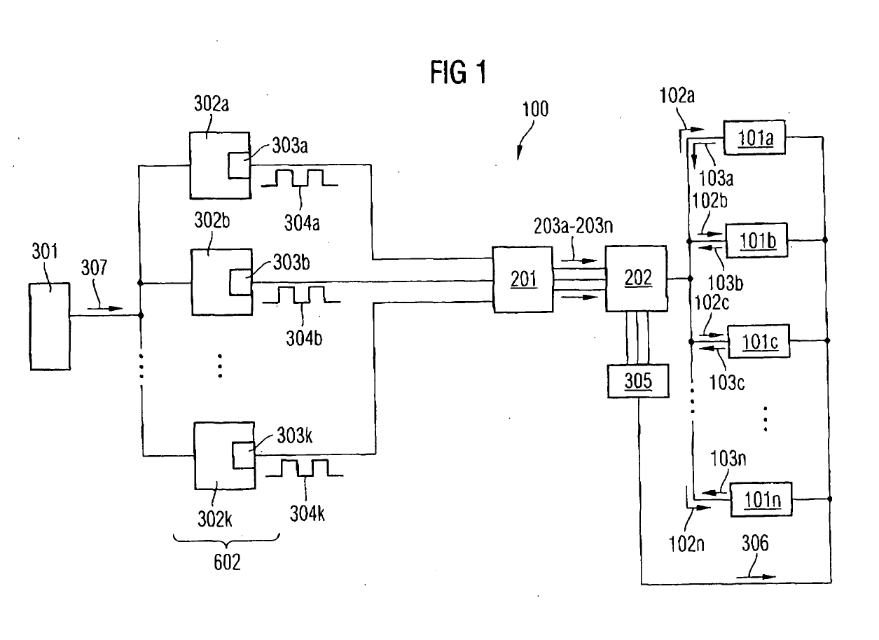

FIG. 1 shows a schematic block diagram of an electronic test apparatus in accordance with one preferred exemplary embodiment of the present invention. The reference symbols 101a-101n are used to denote electronic circuit units which are to be tested and, for example, are in the form of memory modules (DRAM, Dynamic Random Access Memory) or other circuit units to be tested which have to be tested at a high clock frequency (signal frequency). To this end, tester signals 102a-102n which are generated by a processing device 201 are supplied to the circuit units to be tested 101a-101n. The tester signals form a desired data stream which is subsequently compared, in a comparison unit (not shown) of the processing device 201, with an actual data stream which is output by the circuit units to be tested 101a-101n. In particular, it is important to test the circuit units to be tested, for example the memory modules to be tested, at high clock frequencies.

The fundamental components of the inventive test apparatus include a clock signal generator 301, a driver device 602, the processing device 201, a connecting device 202 and a combinational logic device 305. It shall be pointed out that, in order to obtain a clear illustration, other components which are not needed to understand the invention have been omitted in the simplified block diagram shown in FIG. 1 and are therefore not described.

The driver device 602 has individual driver units, that is to say the driver subunits 302a-302k. In accordance with one preferred exemplary embodiment of the present invention, the number of driver subunits 302a-302k is k=2. In the driver subunits 302a-302k, the clock signal 307 generated by the clock generator 301 is respectively supplied in a parallel manner. Each of the driver subunits 302a-302k respectively contains a phase shifter unit 303a-303k. The phase shifter unit ensures a relative phase shift between the driver signals output from the driver subunits 302a-302k such that respective phase-shifted driver signals 304a-304k are obtained. In order to combine the phase-shifted driver signals 304a-304k to form a clock combination signal 306, it is advantageous if the phase shifter units 303a-303k respectively shift the clock signal 307 by fixed amounts. For example, the phase-shifted driver signals 304a-304b must be phase-shifted through 180° relative to one another when using k=2 phase shifter units and k=2 driver subunits. In the case of such differential clocking, the clock combination signal 306 shown in FIG. 5 is obtained. All of the output signals, that is to say the phase-shifted driver signals 304a-304k, are supplied, via the processing device 201 and the connecting device 202, to the combinational logic device 305 which logically combines the supplied phase-shifted driver signals 304a-304k to form the clock combination signal 306. The combinational logic device 305 is preferably in the form of an OR gate.

The channels are shorted to one another in order to form the clock combination signal 306. The clock combination signal 306 is supplied to at least one circuit unit to be tested 101a-101n. The clock signal 307 is supplied to the processing device 201 in which desired data 203a-203n, which are generated in the processing device 201, are compared with actual data 103a-103n, which are output from the circuit units 101a-101n, on the basis of the clock signal 307 supplied. The desired data 203a-203n output from the processing device 201 are supplied, via the connecting device 202, to the circuit units to be tested 101a-101n. The connecting device is designed in such a manner that it interchanges the phase-shifted clock signals 304a-304k, desired data 203a-203n and actual data 103a-103n between the processing device 201, the combinational logic device 305 and the at least one circuit unit to be tested 10la-101n.

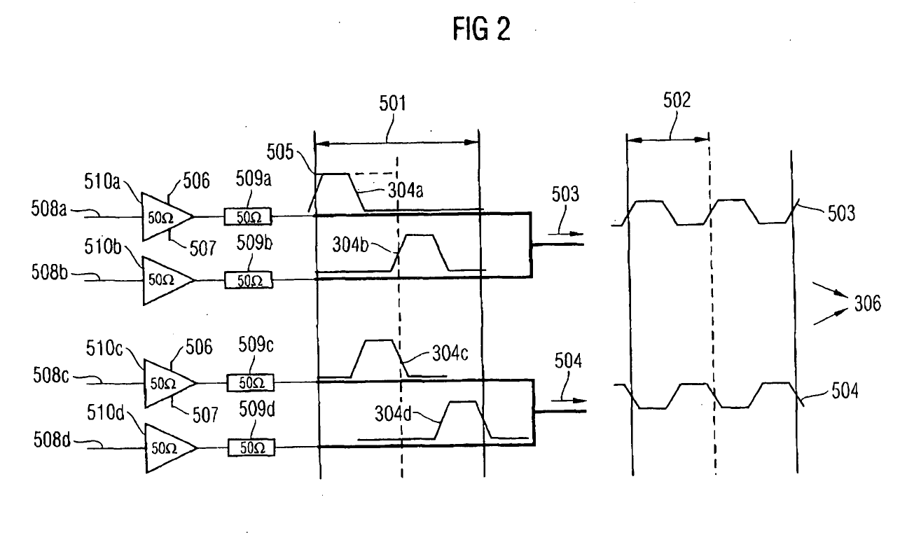

FIG. 2 shows a method for increasing the clock frequency in accordance with one preferred exemplary embodiment of the invention. In this method, two tester channels are physically connected to one another and are operated using two phase-shifted signals with a reduced pulse width in order to generate a combined signal, that is to say a clock combination signal 306 (see FIG. 1).

The clock combination signal 306 is at twice the frequency of the individual signals. For this purpose, four channels 508a, 508b, 508c and 508d are respectively terminated with transmitter resistors 509a, 509b, 509c and 509d via respective driver elements 510a, 510b, 510c and 510d. In the preferred exemplary embodiment of the present invention, the transmitter resistors have a resistance of 50 ohms. In one particular embodiment, the transmitter resistors are designed to be parts of the channels 508a-508d which are operated with a maximum operating voltage 506 and a minimum operating voltage 507, that is to say a maximum voltage and a minimum voltage. The signals output from the transmitter resistors 509a-509d are combined with one another, in the form of phase-shifted driver signals 304a, 304b, 304c and 304d, using a corresponding tester signal 503 and an inverted tester signal 504. More precisely, the first two phase-shifted driver signals 304a and 304b are combined to form the tester signal 503, while the following two phase-shifted driver signals 304c and 304d are converted into the inverted tester signal 504. In this case, the tester signals 503 and 504 have a logic H level 505.

Following combination, the tester repetition period 501 can thus be reduced, that is to say in such a manner that the tester signal 503 and the inverted tester signal 504 have only half the tester repetition period 502. The frequency of the input clock signal is doubled in this manner. As shown in FIG. 2, the phase-shifted driver signals 304a, 304b form a non-inverted tester signal 503, while the two lower phase-shifted driver signals 304c, 304d form a phase-shifted driver signal 504. The clock combination signal 306 which is provided at twice the frequency of the individual clock signals 307 is obtained in this manner using differential clocking. It shall be pointed out that, in principle, more than four phase-shifted driver signals 304a-304d and more than four driver channels 508a-508d can be used to generate the clock combination signal 306.

The advantage of the method illustrated in FIG. 2 resides in the fact that each driver (not shown) is correctly terminated with a 50 ohm impedance at the end of the driver channel 508a-508d. Consequently, each wave of a clock signal which is passed to the circuit unit to be tested 101a-101n (FIG. 1) and continues to propagate to another driver subunit will be absorbed by such a transmitter resistor. This means that multiple reflections do not occur within the test system.

With a tester repetition period 501 of 4 ns, such clock combination signal pulse generation allows a tester frequency of up to 500 MHz if a clock signal 307 having a fundamental frequency of 250 MHz is used.

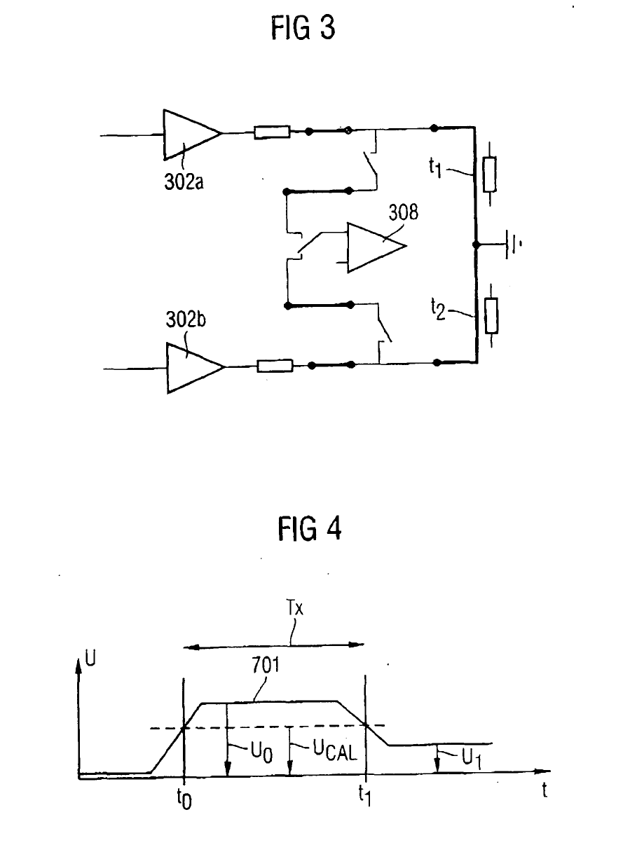

Another aspect of the present invention is to calibrate the arrangement. FIG. 3 shows, by way of example, two driver subunits 302a and 302b. Such calibration is required since at least two drivers (when using two phase-shifted driver signals) have to be combined in the connecting device 202 which may be provided in the form of a HiFix device. In this manner, the test system cannot carry out combination calibration using free connection pins. FIG. 3 shows adaptation of the calibration method to the new arrangement. The adapted calibration is based on the fact that the circuit unit to be tested is temporarily shorted to earth in order to correctly reflect the incoming calibration waves. Each driver subunit 302a, 302b is calibrated separately, as during the conventional calibration of a conventional test system.

FIG. 4 shows the corresponding calibration signals 701. In this case, a voltage profile U is plotted as a function of time t. A calibration voltage results from the following formula:
UCAL=U02/(2U0−U1),
where: Tx=t1−t0.

Measuring the two voltages U0 and U1 makes it possible to calculate the calibration voltage UCAL. This voltage corresponds exactly to the threshold voltage which is used to measure the times t1 and t0. The propagation delay Tx can consequently be determined in accordance with the above formula. Like the combination calibration of the test system, such an adapted calibration procedure has the advantage that only one comparator 308 (see FIG. 3) is required. This leads to more accurate results than in a situation in which a plurality of comparators, for example IO comparators, are used for calibration.

FIG. 5 illustrates measurement results for determining the accuracy of the generation of a clock combination signal 306. FIG. 5 shows two voltage profiles U as a function of a measurement time t. The two voltage profiles together produce the clock combination signal 306. The voltage profiles may be, for example, a tester signal 503 and an inverted tester signal 504, as explained with reference to FIG. 2. Such differential clocking makes it possible, in principle, to double the frequency, an intersection point range of the zero crossings of the tester signals 503, 504 being used as a measure of the accuracy of frequency doubling. Such an accuracy range is illustrated using a region which is labelled with the reference symbol 603 in FIG. 5 (hatched region).

The results show that, as a result of the hard-wired OR method, it is possible to generate signals at frequencies of up to 420 MHz using a conventional Advantest 5581H ATE system with specified tester accuracies of ±180 ps driver skew. Future applications of this method are based on improved calibration adaptation and more precise tuning of each driver group.

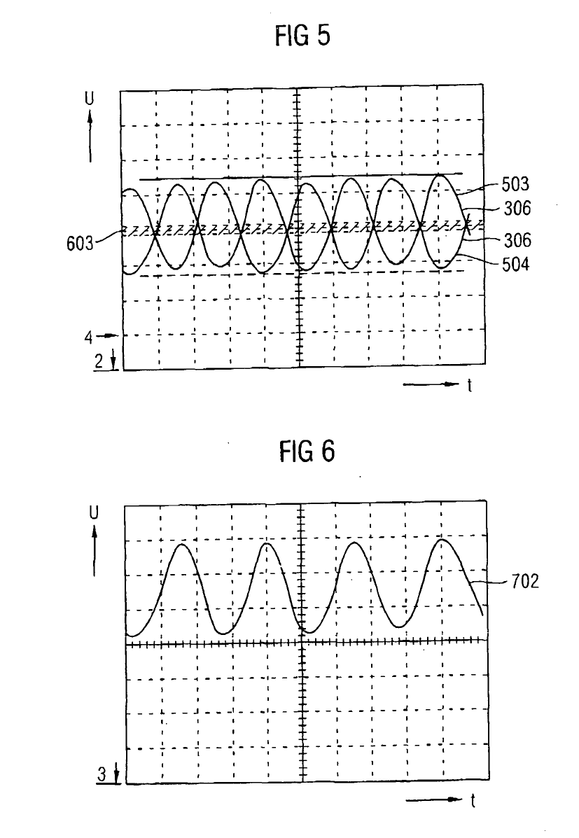

FIG. 6 illustrates the output signal from a standard driver subunit, that is to say a generated clock signal at 400 MHz with an amplitude of 500 mV.

As in FIG. 5, FIG. 6 also illustrates a voltage profile U as a function of a measurement time t. The amplitude of the generated wave 702 is approximately 500 mV.

The inventive electronic test apparatus and the inventive test methods, which are based, on the one hand, on the use of a combinational logic device 305 which is in the form of an OR gate and, on the other hand, on a hard-wired OR operation, thus make it possible to considerably increase the signal frequency of the test apparatus which can be used to test electronic circuit units to be tested 101a-101n. This makes it possible to design conventional test apparatuses in such a manner that they are suitable for testing circuit units which are to be tested and operate at a considerably higher clock rate than can be provided by the conventional test system.

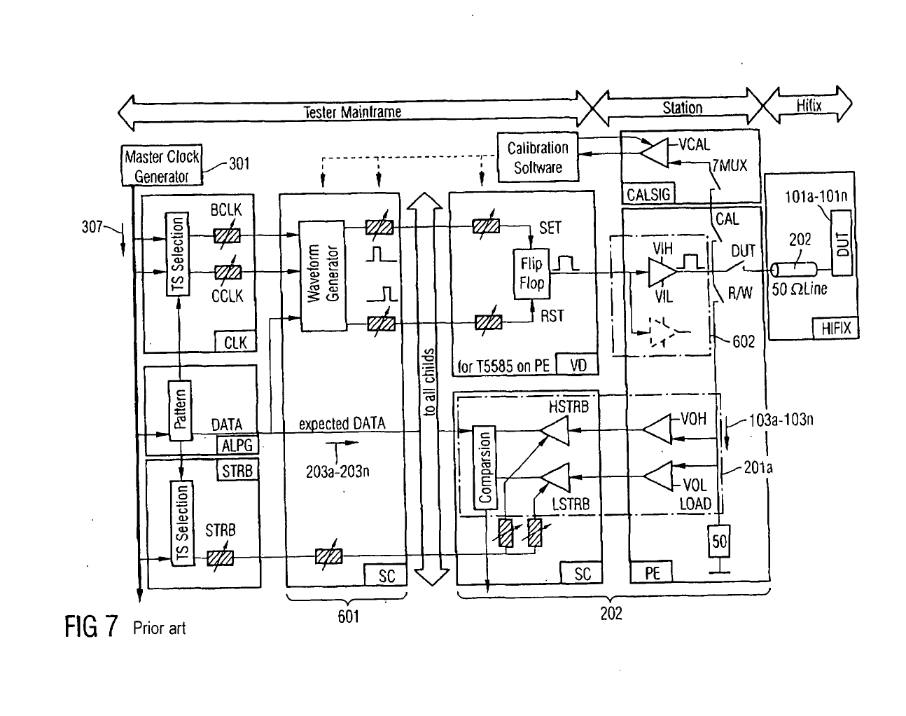

As regards the conventional electronic test apparatus which is illustrated in FIG. 7 and is intended to test circuit units to be tested, reference is made to the introduction to the description.

Although the present invention was described above with reference to preferred exemplary embodiments, it is not restricted thereto but rather can be multifariously modified.

In addition, the invention is not restricted to the possible applications mentioned.

What is claimed is:

1. An electronic test apparatus for testing at least one circuit unit, comprising:
a clock signal generator for generating a clock signal;
a driver device comprising a plurality of driver subunits each generating a phase-shifted driver signal in response to said clock signal;
a processing device for processing said phase-shifted driver signals and for comparing actual data being output by at least one circuit unit with desired data generated in said processing device;
a connecting device for connecting said processing device to said at least one circuit unit and for transmitting said phase-shifted driver signals, said desired data, and said actual data between said processing device and said at least one circuit unit; and
a combinational logic device for combining said phase-shifted driver signals to form a clock combination signal.

2. The apparatus of claim 1, wherein said driver device comprises exactly two driver subunits.

3. The apparatus of claim 1, wherein each of said driver subunits comprises a phase shifter unit providing a predetermined phase shift of said driver signal.

4. The apparatus of claim 1, wherein said combinational logic device is an OR gate.

5. The apparatus of claim 1, wherein said connecting device comprises a HiFix unit.

6. The apparatus of claim 1, wherein said driver subunits are terminated with a line impedance.

7. The apparatus of claim 3, wherein each of said phase shifter units provides a gradual phase shift of said driver signal.

8. The apparatus of claim 1, wherein said phase-shifted driver signals are logically combined by hard-wiring them to a predetermined transmitter resistor.

9. The apparatus of claim 8, wherein said hard-wiring to said predetermined transmitter resistor is in the form of an OR operation.

10. The apparatus of claim 8, wherein said predetermined transmitter resistor has an impedance of 50 ohms.

11. A method for testing at least one circuit unit, comprising the steps of:
generating a clock signal utilizing a clock signal generator;
driving said clock signal utilizing a driver device;
processing said clock signal utilizing a processing device;
generating desired data utilizing said processing device;
transmitting said clock signal, said desired data and actual data being output by a circuit unit in response to said desired data between said processing device and said at least one circuit unit utilizing a connecting device provided between said processing device and said at least one circuit unit;
comparing said actual data with said desired data utilizing said processing device;
generating phase-shifted driver signals utilizing a plurality of driver subunits of said driver device;
supplying said phase-shifted driver signals to said processing device;
generating a clock combination signal by combining said phase-shifted driver signals utilizing a combinational logic device; and
supplying said combination signal to said at least one circuit unit.

12. The method of claim 11, wherein said clock signal has a frequency and said clock combination signal is provided at twice said frequency.

13. The method of claim 12, wherein said clock combination signal is obtained using differential clocking.

14. The method of claim 11, wherein a clock signal repetition period is four nanoseconds.
